(19) United States
(12) Patent Application Publication
(10) Pub. No.: US 2025/0309044 A1
(43) Pub. Date: Oct. 2, 2025

(54) THERMAL IMPROVEMENT SYSTEMS FOR ELECTRONIC DEVICES AND METHODS OF FORMING THE SAME

(71) Applicant: Adeia Semiconductor Bonding Technologies Inc., San Jose, CA (US)

(72) Inventors: Laura Wills Mirkarimi, Sunol, CA (US); Rajesh Katkar, Milpitas, CA (US); Cyprian Emeka Uzoh, San Jose, CA (US); Thomas Workman, San Jose, CA (US); Suhail Jaan Sadiq, Dublin, CA (US)

(21) Appl. No.: 18/750,753

(22) Filed: Jun. 21, 2024

Related U.S. Application Data
(60) Provisional application No. 63/571,849, filed on Mar. 29, 2024.
(60) Provisional application No. 63/651,775, filed on May 24, 2024.

(51) Int. Cl. H01L 23/427; H01L 23/00; H01L 23/373

(52) U.S. Cl. CPC H01L 23/427; H01L 23/3737; H01L 24/32; H01L 2224/32225

(57) ABSTRACT

Embodiments herein provide for an integrated cooling assembly comprising a semiconductor device and a heat pipe. The heat pipe comprises a non-metal material attached to a backside of the semiconductor device, or a metal material attached to a backside of the semiconductor device via a flexible material structure. The heat pipe comprises a shell defining a heat pipe chamber. The shell having an inner surface and an outer surface, and the inner surface of the heat pipe chamber includes a wick material.

### CROSS-REFERENCE TO RELATED APPLICATIONS

The present disclosure claims the benefit of U.S. Provisional Patent Application No. 63/571,849, filed Mar. 29, 2024 and U.S. Provisional Patent Application No. 63/651,775 filed May 24, 2024, each of which is hereby in incorporated by reference herein in its entirety.

### FIELD

The present disclosure relates to advanced packaging for microelectronic devices, and in particular, cooling systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling since even small increases in operating temperatures can negatively impact the performance of microprocessors, memory devices, and other electronic components. While some of this energy is expended to operate the cooling systems that are directly cooling the chips (e.g., heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high performance chips in server racks and each of those high performance chips is a heat source. An uncontrolled ambient temperature in a data center will adversely affect the performance of the individual chips and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc. have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface material(s), such as, for example, thermal paste, thermal adhesive, or thermal gap filler, may be used to facilitate heat transfer between the surfaces of a chip and heat dissipation device(s). A thermal interface material(s) (TIM(s)) is any material that is inserted between two components to enhance the thermal coupling therebetween. Unfortunately, the combined thermal resistance of (i) the thermal resistance of interfacial boundary regions between a TIM(s) and the chip and/or the heat dissipation device(s); and (ii) the thermal resistance of a thermal interface material(s) itself can inhibit heat transfer from the chip to the heat dissipation devices, undesirably reducing the cooling efficiency of the cooling system.

Generally speaking, there are multiple components between the heat dissipating sources (i.e., active circuitry) in the chips and the heat dissipation devices, each of which contribute to the system thermal resistance accumulatively along the heat transfer paths and raise chip junction temperatures from the ambient.

Such cooling systems can suffer from reduced cooling efficiency due to the design and manufacture of system components. Some devices, for various reasons, cannot employ active cooling, and thus the passive heat dissipation from such devices provides an upper limit of device processing power and device heat and power dissipation. In an effort to reduce the operating temperature of such devices, whilst enabling an increase in processing power thereof, it is desirable to increase the heat dissipation envelope. Accordingly, heat may be dissipated from such devices by improving the heat transfer characteristics of a passive cooling arrangement.

Accordingly, there exists a need for improved energy-efficient cooling systems, by reducing system thermal resistance, and methods of manufacturing the same.

### SUMMARY

Embodiments herein provide cooling assemblies attached to advanced device packages. Advantageously, the integrated device cooling assemblies deliver appropriate cooling directly to a semiconductor device so as to obtain effective cooling of the device.

A first general aspect includes an integrated cooling assembly comprising a semiconductor device and a heat pipe attached to a backside of the semiconductor device. The heat pipe comprises an organic material. The heat pipe comprises a shell defining a heat pipe chamber, the heat pipe shell having an inner surface and an outer surface. The inner surface of the heat pipe shell includes a wick material.

Implementations of the cooling assembly according to the first general aspect may include one or more of the following features. The organic material may comprise a polymer. The heat pipe may comprise a composite material. The composite material may comprise organic material and thermally conductive particulates.

The heat pipe may be attached to the backside of the semiconductor device with adhesive, direct dielectric bonds, or hybrid bonds. In some embodiments, a region of the outer surface of the heat pipe includes a dielectric layer deposited thereupon. The dielectric layer may be disposed between a region of the outer surface of the heat pipe and the backside of the semiconductor device. The heat pipe may be attached to the backside of the semiconductor device using direct dielectric bonds formed between the dielectric layer and the backside of the semiconductor device. The dielectric layer may further include conductive features thereupon. The backside of the semiconductor device may further include conductive features, and the heat pipe may be attached to the backside of the semiconductor device using hybrid bonds comprising the direct dielectric bonds and direct bonds formed between the conductive features disposed in the backside of the semiconductor device and the conductive features disposed in the dielectric layer.

In some embodiments, the heat pipe is attached to the backside of the semiconductor device via a flexible material structure comprising an organic material. The flexible material structure may comprise a composite material. The composite material may comprise organic material and thermally conductive particulates. The flexible material structure may comprise one or more metal vias. The heat pipe may be attached to the flexible material structure with direct dielectric bonds, or hybrid bonds. In some embodiments, a region of the outer surface of the heat pipe includes a dielectric layer deposited thereupon. The dielectric layer may be disposed between a region of the outer surface of the heat pipe and the flexible material structure. The heat pipe may be attached to the flexible material structure using direct dielectric bonds formed between the dielectric layer and the flexible material structure. The dielectric layer may further include conductive features thereupon. The flexible material structure may further include conductive features thereupon, and the heat pipe may be attached to the flexible material structure using hybrid bonds comprising the direct dielectric bonds and direct bonds formed between the conductive features disposed in the dielectric layer and the conductive features disposed in the flexible material structure. The flexible material structure may be attached to the backside of the semiconductor device with direct dielectric bonds. The flexible material structure may further include conductive features thereupon. The backside of the semiconductor device may further include conductive features, and the flexible material structure may be attached to the backside of the semiconductor device using hybrid bonds comprising the direct dielectric bonds and direct bonds formed between the conductive features disposed in the backside of the semiconductor device and the conductive features disposed in the flexible material structure.

In some embodiments, one or more dummy chiplets may be attached to the heat pipe. The one or more dummy chiplets may be attached to a casing via a thermal interface material.

In some embodiments, a backside of the semiconductor device may form a portion of the shell of the heat pipe. The backside of the semiconductor device may form a portion of the inner surface of the shell of the heat pipe. A wick material may extend across the portion of the backside of the semiconductor device that forms the portion of the shell. The wick material which extends across the portion of the backside of the semiconductor device may be dendritic metal layer, for example dendritic copper or copper alloy grown on the backside of the semiconductor device.

In some embodiments, the heat pipe comprises a first portion comprising an organic material and a second portion comprising a metal material. A region of the first portion of the heat pipe is attached to the backside of the semiconductor device. The heat pipe may have a proximal end and a distal end. The proximal end of the heat pipe may be attached to the backside of the semiconductor device. The distal end of the heat pipe may be attached to a heat sink.

A second general aspect includes an integrated cooling assembly including a semiconductor device and a metal heat pipe attached to the semiconductor device via a flexible material structure. The flexible material structure comprises an organic material or a composite material. The composite material may comprise the organic material and thermally conductive particulates. The flexible material structure may comprise one or more metal vias. The heat pipe may be attached to the flexible material structure using adhesive, direct dielectric bonds, or hybrid bonds. The flexible material structure may be attached to the heat pipe using direct dielectric bonds or hybrid bonds. The heat pipe may have a proximal end and a distal end. The proximal end of the heat pipe may be attached to the backside of the semiconductor device. The distal end of the heat pipe may be attached to a heat sink.

A third general aspect includes a method of manufacturing an integrated cooling assembly. The method comprises attaching a heat pipe to a backside of a semiconductor device. The heat pipe comprises an organic material. The method may include depositing a dielectric layer on a region of the heat pipe prior to directly bonding the dielectric layer to the semiconductor device. Directly bonding the dielectric layer to the semiconductor device may comprise forming direct dielectric bonds between the dielectric layer and the backside of the semiconductor device. The method may include forming the heat pipe by attaching a first portion of the heat pipe to a second portion of the heat pipe. The first portion may comprise organic material or a composite material. The composite material may comprise the organic material and thermally conductive particulates. The second portion may comprise a metal material. The first portion of the heat pipe may be attached to the second portion of the heat pipe with adhesive.

In some embodiments, the method may include depositing a first dielectric layer on a first region of the heat pipe prior to directly bonding the first dielectric layer to the semiconductor device. The method may include depositing a second dielectric layer on a second region of the first portion of the heat pipe. The method may include depositing a third dielectric layer on a third region of the second portion of the heat pipe. Attaching the first portion of the heat pipe to the second portion of the heat pipe may comprise directly bonding the second dielectric layer to the third dielectric layer to form direct dielectric bonds.

A fourth general aspect includes a method of manufacturing an integrated cooling assembly. The method comprises attaching a metal heat pipe to a flexible material structure and attaching the flexible material structure to a backside of a semiconductor device. The metal heat pipe may be attached to the flexible material structure with adhesive, direct dielectric bonds, or hybrid bonds. The flexible material structure may be attached to the backside of the semiconductor device using direct dielectric bonds or hybrid bonds.

### BRIEF DESCRIPTION OF THE DRAWINGS

The above and other objects and advantages of the disclosure will be apparent upon consideration of the following detailed description, taken in conjunction with the accompanying drawings, in which:

FIG. 1A illustrates a device package with an external heat pipe;

FIG. 1B is a schematic view of a cooling arrangement which includes a heat pipe, in accordance with some embodiments of the present disclosure;

FIG. 2 is a schematic view of a cooling arrangement which includes a heat pipe cooler, in accordance with some embodiments of the present disclosure;

FIG. 3A shows illustrative schematic sectional side view of a portion of an example electronic device, in accordance with some embodiments of the present disclosure;

FIGS. 3B-3C shows illustrative schematic sectional side views of a portion of examples of an electronic device, in accordance with some embodiments of the present disclosure;

FIGS. 4A-4D show an illustrative schematic sectional side view of examples of a cooling assembly, in accordance with some embodiments of the present disclosure;

FIG. 5 is a schematic view of a heat pipe, in accordance with some embodiments of the present disclosure;

FIGS. 6A-6G illustrate schematic sectional side views of examples of forming a cooling assembly for an electronic device at different stages of manufacturing, in accordance with some embodiments of the present disclosure;

FIGS. 7A-7B illustrate schematic sectional side views of examples of an electronic device, in accordance with some embodiments of the present disclosure;

FIGS. 8A-8D illustrate schematic sectional side views of examples of forming a cooling assembly at different stages of manufacturing, in accordance with embodiments of the present disclosure;

FIGS. 9A-9B illustrate schematic sectional side views of examples of forming a cooling assembly for an electronic device at different stages of manufacturing, in accordance with some embodiments of the present disclosure; and

FIGS. 10A-10B illustrate schematic sectional side views of examples of forming a cooling assembly for an electronic device at different stages of manufacturing, in accordance with some embodiments of the present disclosure.

The figures herein depict various embodiments of the for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term substrate also includes “semiconductor substrates” that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axis in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding”, or “directly bonded”). In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (1^{st}) nonconductive feature directly bonded to another (2^{nd}) nonconductive feature, and ii) at least one (1^{st}) conductive feature directly bonded to another (2^{nd}) conductive feature, without any intervening adhesive. In some hybrid bonding embodiments, there are many 1^{st} conductive features, each directly bonded to a 2^{nd} conductive feature, without any intervening adhesive. In some embodiments, nonconductive features on the first element are directly bond to nonconductive features of the second element at room temperature without any intervening adhesive, which is followed by bonding of conductive features of the first element directly bonded to conductive features of the second element at via annealing at slightly higher temperatures (e.g., >100° C., >200° C., >250° C., >300° C., etc.).

Unless otherwise noted, the terms “cooling assembly” and “integrated cooling assembly” generally refers to a semiconductor device and a cooler such as a heat pipe, heat spreader, or cold plate attached to the semiconductor device. The cooler may comprise a polymer material. The cooler may be attached to the semiconductor device by use of a compliant adhesive layer or by direct dielectric or hybrid bonding. For example, the cooler may include material layers and or metal features which facilitate direct dielectric or hybrid bonding with the semiconductor device. Beneficially, the backside of the semiconductor device is directly exposed to the cooler (e.g., fluids within a heat pipe), thus providing for direct heat transfer therebetween. Unless otherwise noted, the integrated cooling assemblies described herein may be used with any desired fluid, e.g., liquid, gas, and/or vapor-phase coolants, such as water and/or glycol, for example.

Exemplary fluids available for use in the various thermal solution embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Additionally, depending upon design and operating conditions, these fluids may be used in single-phase liquid, single-phase vapor, two-phase liquid/vapor or two-phase solid/liquid. All of these fluids and fluid mixtures will alter the thermohydraulic and heat transfer properties by altering the temperatures where phase change occurs, as well as meeting design temperature and pressure conditions for the component being cooled or warmed and the thermal solution being deployed. Additionally, multiple combinations of the fluid phases may be employed in various hybrid configurations to meet the particular cooling or warming needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a thermal solution system using the disclosed embodiments, engineered dielectric cooling fluids may be used. Some examples of dielectric fluids used for cooling semiconductors include: 3M™ Fluorinert™ Liquid FC-40—A non-flammable, dielectric fluid that can be used in direct contact with live electronics; 3M™ Novec™ Engineered Fluids—A non-flammable, dielectric fluid that can be used in direct contact with live electronics; Galden® PFPE (perfluoropolyether) products used as heat transfer fluids; EnSolv Fluoro HTF—A solvent with a high boiling point and low pour point that can be used for semiconductor wafer cooling. It is understood that in the selection of the cooling fluid, system design aspects such as operating temperatures and pressures, fluid flow rates, fluid viscosity, and other properties will require evaluation when selecting the appropriate cooling fluid.

In some embodiments, the cooling fluids may contain microparticles and/or nanoparticle additives to enhance the conductivity of the cooling fluid within the integrated cooling assemblies. Choi and Eastman (1995) from Argonne National Laboratory, U.S.A. (Yu et al., 2007) coined the word “nanofluid”. Nanofluids are engineered fluids prepared by suspending the nano-sized (1-100 nm) particles of metals/non-metals and their oxide(s) with a base/conventional fluid. The suspension of high thermal conductivity metals/non-metals and their oxides nanoparticles enhances the thermal conductivity and heat transfer ability, etc. of the base fluid. The additives to the underlying cooling fluid may comprise for example, nanoparticles of carbon nanotube, nanoparticles of graphene, or nanoparticles of metal oxides. When the cooling fluid contains microparticles, the microparticles are typically 10 microns or less in diameter. Silicon oxide microparticles may be used.

The volume concentration of these micro or nanoparticles may be less than 1%, less than 0.2%, or less than 0.05%. Depending upon the liquid and micro/nanoparticle type chosen for the cooling fluid, higher volume concentrations of 10% or less, 5% or less, or 2% or less may be used. The cooling fluids may also contain small amounts of glycol or glycols (e.g. propylene glycol, ethylene glycol etc.) to reduce frictional shear stress and drag coefficient in the cooling fluid within the integrated cooling assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au, etc.), metal oxides (e.g., TiO₂, Al₂O₃, CuO, etc.), carbons (e.g. CNTS, graphene, diamond, graphite . . . etc.), or a mixture of different types of nanomaterials. Metal nanoparticles (Cu, Ag, Au . . . ), metal oxide nanoparticles (Al₂O₃, TiO₂, CuO), and carbon-based nanoparticles are commonly employed elements. Silicon oxide nanoparticles may also be used. Using cooling fluids with micro and/or nanoparticles when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nanoparticles. Magnetic nanoparticles may be coated with surfactant layers such as oleic acid to reduce particle agglomeration and/or settling. Magnetic nanoparticles used in MNFs are usually made of metal materials (ferromagnetic materials) such as iron, nickel, cobalt, as well as their oxides such as spinel-type ferrites, magnetite (Fe₃O₄), and so forth. The magnetic nanoparticles used in MNFs typically range in size from about 1 to 100 nanometers (nm).

As described below, a cooler which is formed of a heat pipe or heat pipes may be used to control the temperature of semiconductor devices. The fluid within the heat pipe or heat pipes may absorb heat and conduct heat away from the semiconductor device.

The present disclosure describes embodiments involving the architecture of system and component elements that can be employed to provide for the cooling of semiconductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems (not shown) to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the present disclosure and terms used should be viewed in a light that also considers the design option for such warm-up or heat-up. Thus, where terms such as cooling channel, cooling chamber volume, and cooling port are used, such terms could also be considered as a thermal control channel, a thermal control volume, or a thermal control port, respectively. Those skilled in the art would understand that heat flux or heat transfer would go in a different direction, but the design concepts are similar and can be successfully employed in the various embodiments.

A heat pipe or heat pipe cooler is a heat-transfer device that employs phase transition to transfer heat energy. At a hot interface (or hot end) of a heat pipe, that is to say the portion of the heat pipe which is in contact with a heat source, a volatile liquid in contact with a thermally conductive solid surface turns into a vapor by absorbing heat from that surface. The vapor then travels along the heat pipe to a cold interface (or cool end). The cold interface may for example be a heat sink, or the wall or casing or a cooling fan of a device such as a mobile device, a computing device, a handheld device, or similar devices. At the cold interface, the vapor condenses back into a liquid, releasing the latent heat. The liquid then returns to the hot interface through various mechanisms (e.g., capillary action, wicking effect, centrifugal force, gravity, etc.), and the cycle repeats.

Because of the high heat transfer coefficients involved in boiling and condensation, heat pipes are effective thermal conductors. The effective thermal conductivity may vary with the length of a heat pipe and can approach 100 kW/(m·K) for long heat pipes, in comparison with approximately 0.4 kW/(m·K) for heat transfer using plain copper alone. Heat pipes are generally made of hollow copper pipes and employ water as a working fluid. A working fluid of a heat pipe is captive within the heat pipe and vaporization and subsequent condensation of the working fluid affects the cooling effect provided by the heat pipe. Use of heat pipes is common in consumer electronic devices such as mobiles, desktops, laptops, tablets, smartphones, etc.

A typical heat pipe generally consists of a sealed pipe or tube made of a material that is compatible with the working fluid, such as copper for water heat pipes, or aluminum for ammonia heat pipes. The working fluid could be water, distilled water, water mixed with a surfactant, water mixed with another fluid for improved viscosity management, etc. Typically, a vacuum pump is used to evacuate the interior of the heat pipe to remove the air from the empty heat pipe. The heat pipe is generally partially filled with a working fluid and then sealed. The working fluid mass is chosen so that the heat pipe contains both vapor and liquid over the operating temperature range. In the case of heat pipes to be used with a consumer electronics device, the heat pipe may be formed of copper and employ water as the working fluid. Heat pipes typically contain no mechanical moving parts and therefore require minimal maintenance. Heat pipes generally include an outer wall which forms the heat pipe shell, a wick, and a working fluid. Efficient wicking material may have good thermal conductivity to transport from the heat source to the cooling liquid; may support the capillary action to transfer the condensed liquid back to the heat source; and may have the capability to resist the high temperatures involved. Few examples of the wicking media can include homogenous wicking media such as metal fibers (e.g., made out of metals such as copper, aluminum, nickel, stainless steel, titanium, metal alloys, etc.), porous metals (e.g., porous copper), wire meshes (e.g., core wires), fibrous or dendritic materials, glass fibers, woven cloths or composite wicking media. Heat pipes are designed for very long term operation with minimal maintenance, so the heat pipe shell and wick are preferably compatible with the working fluid.

Heat pipes containing graphene may improve cooling performance in electronics.

A heat pipe employs phase change to transfer thermal energy from one point to another by the vaporization and condensation of a working fluid or coolant. Heat pipes rely on a temperature difference between the ends of the pipe, and cannot lower temperatures at either end below the ambient temperature (hence they tend to equalize the temperature within the pipe). Generally speaking, when one end of the heat pipe is heated, the working fluid inside the pipe at that end vaporizes and increases the vapor pressure inside the cavity of the heat pipe. The latent heat of vaporization absorbed by the working fluid reduces the temperature at the hot end of the pipe.

The vapor pressure over the hot liquid working fluid at the hot end of the pipe is higher than the equilibrium vapor pressure over the condensing working fluid at the cool end of the pipe, and this pressure difference drives a rapid mass transfer to the condensing end where the excess vapor condenses, releases its latent heat, and warms the cool end of the pipe. Noncondensing gases (caused by contamination for instance) in the vapor impede the gas flow and reduce the effectiveness of the heat pipe, particularly at low temperatures, where vapor pressures are low. The speed of molecules in a gas is approximately the speed of sound, and in the absence of noncondensing gases (i.e., if there is only a gas phase present) this is the upper limit to the velocity with which they could travel in the heat pipe. In practice, the speed of the vapor through the heat pipe is limited by the rate of condensation at the cooler end and far lower than the molecular speed.

For a heat pipe to transfer heat, it typically contains saturated liquid and its vapor (the saturated liquid in gas phase). The saturated liquid vaporizes and travels within the heat pipe to the cold interface of the heat pipe, which may act as a condenser, cooling the vapor, condensing it, and turning it back to a saturated liquid. In a typical heat pipe, the condensed liquid is returned to the evaporator using a wick structure exerting a capillary action on the liquid phase of the working fluid. Wick structures used in heat pipes may include sintered metal powder, fibrous or dendritic material, wire mesh, screen, and/or grooved wicks, which have a series of grooves parallel to the pipe axis. When the condenser is located above the evaporator in a gravitational field, gravity can return the liquid (e.g., working liquid). In this case, the heat pipe is a thermosiphon. Finally, rotating heat pipes use centrifugal forces to return liquid (e.g., working liquid) from the condenser to the evaporator.

In general, heat may be transferred into the heat pipe from a device or package which generates heat in operation, via the medium of thermal interface material, TIM, often by way of a heat spreader on the device or package. In an example of CPU cooling in a laptop computer, a heat pipe may be thermally attached to the heat spreader of a CPU package (i.e., in thermal contact therewith) within the laptop computer by way of TIM. It is to be understood that further fixing may also be employed, that is to say the heat pipe may be mechanically attached to the PCB onto which the CPU is mounted, and the device end of the heat pipe may be mounted in an attachment portion which may be made of copper or the like, which may aid the thermal contact between the CPU package and the heat pipe.

Heat may pass from the device or package (the CPU package in this case) into the heat pipe via the thermal interface material, with the operation of the heat pipe transferring the heat away from the device or package to the cooler end of the heat pipe which may be affixed to a heatsink, cooler, fan arrangement, or other similar devices. The heatsink, cooler, or fan arrangement may then dump the heat to atmosphere, such that the heat generated by the device or package is transferred away from the device or package and to atmosphere.

As used herein, the terms “chip”, “die”, “device” and “device package” may be used interchangeably.

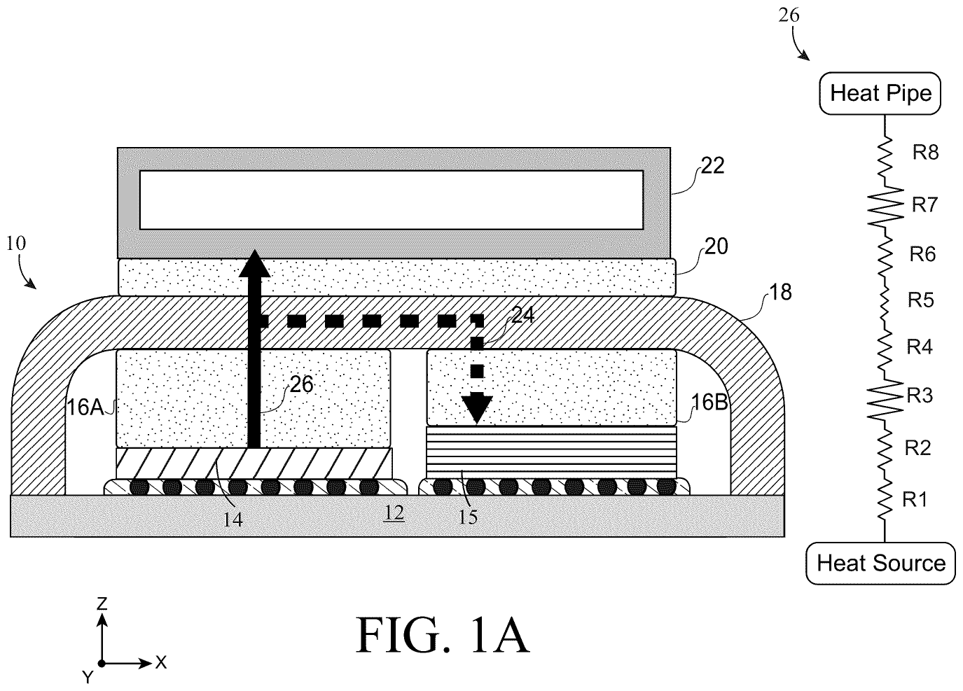

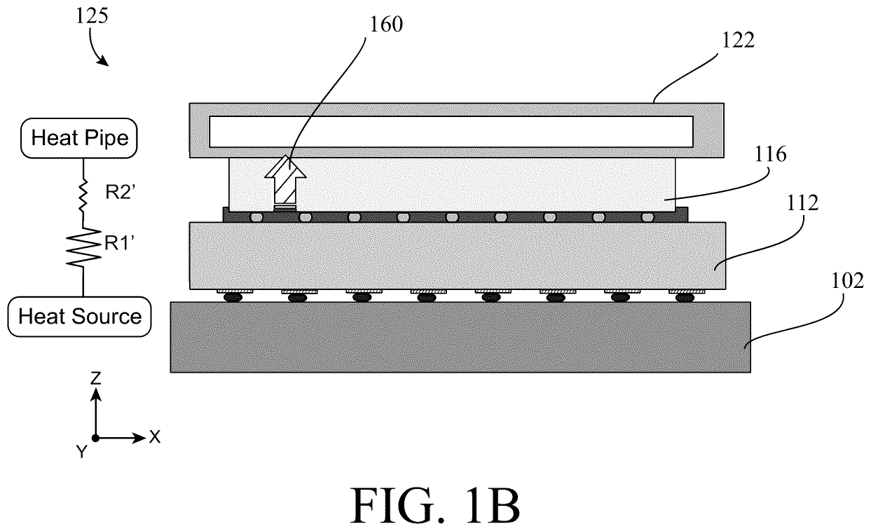

FIG. 1A is a schematic side view of a device package 10 and a heat pipe 22 attached to the device package 10. The device package 10 typically includes a package substrate 12, a first device 14, a device stack 15, a heat spreader 18, and first TIM layers 16A, 16B thermally coupling the first device 14 and device stack 15 to the heat spreader 18. The device package 10 is thermally coupled to the heat pipe 22 through a second TIM layer 20. The TIM layers 16A, 16B, 20 facilitate thermal contact between components in the device package 10 and between the device package 10 and the heat pipe 22.

As heat flux density increases with increasing power density in advanced semiconductor devices, the cumulative thermal resistance of the system illustrated in FIG. 1A is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirable transferred from the first device 14 having a high heat flux, such as a CPU or GPU, to the device stack 15 having low heat flux, such as memory, through the heat spreader 18.

For example, as shown in FIG. 1A, each device package component and the respective interfacial boundaries therebetween has a corresponding thermal resistance which forms heat transfer path 26 (illustrated by arrow 26 in FIG. 1A). The left-hand side of FIG. 1A illustrates the heat transfer path 26 as a series of thermal resistances R1-R8 between a heat source and the heat pipe. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26 and R5 may account for 5% or more. R1 of the first device 14 and R2, R4, R6, and R8 of the interfaces account for the remaining cumulative thermal resistance. Accordingly, embodiments herein provide for integrated cooling assemblies embedded within a device package. The embedded cooling assemblies shorten the thermal resistance path between the semiconductor device and the heat pipe and reduce thermal communication between semiconductor devices disposed in the same device package, such as described in relation to the figures herein.

Turning now to FIG. 1B, a device cooling arrangement 125 is shown. In FIG. 1B, a device 116 and a package substrate 112 are shown. In some embodiments, the device 116 and package substrate 112 may be similar to the device 14 and the package substrate 12 described in FIG. 1A, and therefore the description of similar features is omitted for brevity. The package substrate 112 is attached to a main board 102 which may be a PCB. In the arrangement 125 shown in FIG. 1B, a heat pipe 122 is attached directly to the backside of the device 116. No heat spreader or thermal interface material is present between the device 116 and the heat pipe 122. In some embodiments, some portion of the heat pipe 122 is attached to the backside of the device 116 using an adhesive, thermal interface material, solder, etc. In some embodiments, the heat extraction media of the heat pipe 122 (e.g., wicking material) is in contact with the device 116.

A heat transfer path 160 is shown, which denotes heat transfer from the device 116 into the heat pipe 122.

Between the heat source (in this case the device 116) and the cooler (in this case the heat pipe 122), there are fewer sources of thermal resistance as compared to the arrangement shown in FIG. 1A. Here, R1′ is the thermal resistance of the bulk semiconductor material of the package substrate 112 and R2′ represents the thermal resistance at the interfacial region of the device package 116 and the heat pipe 122 (e.g., the contact resistance).

Therefore, the sources of thermal resistance shown in FIG. 1B include the thermal resistance of the device 116 (e.g., thermal resistance between the heat generating active side at the bottom and device surface on top) and interface thermal resistance between the device 116 and the heat pipe 122.

These two sources of thermal resistance, R1′ and R2′, combine to give a total thermal resistance may be taken as the thermal resistance R, of the silicon of the device 116 and the thermal resistance of the interfacial region. Therefore, the total thermal resistance, R, is R1′+R2′=R (silicon)+R (interface). That which is shown in FIG. 1A includes thermal resistances R1-R8, and that which is shown in FIG. 1B includes thermal resistances R1′ and R2′. The sum of R1′ and R2′ may have a greatly reduced thermal resistance as compared to the sum of R1-R8. Therefore, that which is shown in FIG. 1B may have a significantly reduced thermal resistance as compared to FIG. 1A

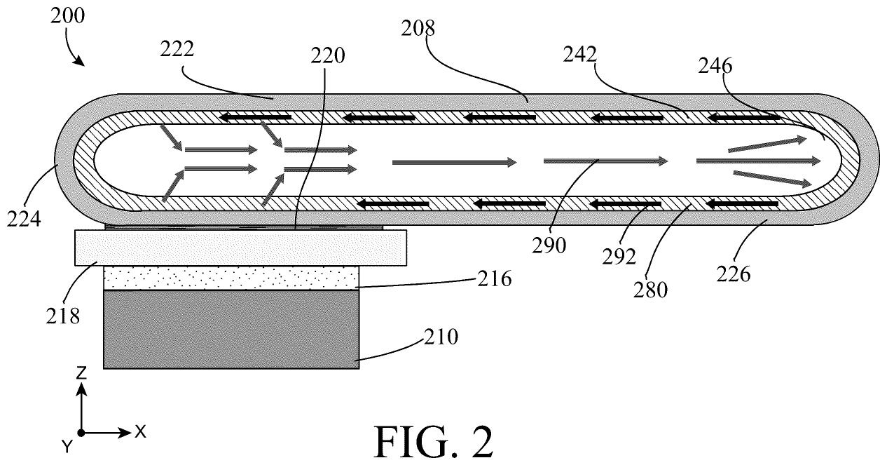

With reference to FIG. 2, a cooling arrangement 200 is shown. A device package or chip 210 is in thermal contact with a metal plate 218 via a layer of TIM 216. In some embodiments, the device package 210 may be similar to the device package 10. In some embodiments, a device (e.g., device 14) may be used in place of device package 10. The metal plate 218 may be the base of a heat pipe cooler 208, similar to the heat pipe coolers described above. The shape and size (or footprint) of the metal plate 206 may be designed so as to match the shape and size/footprint of the device package (or chip) 210. The heat pipe cooler 208 is constructed such that a heat pipe 222 itself is affixed to, and in thermal contact with, the metal plate 218 via a layer of solder 220. However, it is to be understood that any other suitable affixing method may be employed, for example by using brazing, TIM, or adhesive. Heat is transferred from the device package 210 to the heat pipe 222 via the layer of TIM 216, the metal plate 218, and the layer of solder 220. This heat transfer path may affect cooling of the device package 210, with heat transferred from a device end 224 of the heat pipe 222, which may be the end of the heat pipe 222 which is closest to the device package 210, toward a distal end 226 of the heat pipe 222. Heat may then be subsequently transferred away from the distal end 226 of the heat pipe 222 in order to cool the device package 210 by attaching the distal end to the cooling mechanism like a fan, a heat sink, a radiator, etc.

Heat energy from the device package 210 is transferred through the layer of TIM 216, the metal plate 218, the layer of solder 220, and into the heat pipe 222, with each such interface in the heat energy transfer chain presenting thermal resistance.

As can be seen in FIG. 2, heat generated by the device package 210, represented by arrows 290 causes a working fluid in the heat pipe 222 to be vaporized from within a wicking material 242 and into the interior of the heat pipe 222 which comprises a heat pipe chamber 280. The vaporized working fluid, represented by the arrows 290 passes toward a cool end 246 of the heat pipe 222. At the cool end 246 of the heat pipe 222, the working fluid condenses and returns, via the wicking material 242 to the end of the heat pipe 222 at which the device package 210 is affixed. The working fluid may be water, distilled water, water mixed with a surfactant, and/or water mixed with another fluid for improved viscosity management, etc. Few examples of the wicking material may include homogenous wicking media such as metal fibers (e.g., made out of metals such as copper, aluminum, nickel, stainless steel, titanium, metal alloys, etc.), porous metals (e.g., porous copper), wire meshes (e.g., core wires), fibrous or dendritic materials, glass fibers, woven cloths, and/or composite wicking medias. This return flow of the condensed working fluid is denoted by arrows 292 in FIG. 2. This cycle of vaporization and condensation provides cooling of the device package 210. To encourage effective cooling, the cool end 246 of the heat pipe 222 may be attached to a heat sink or similar, which is not shown in FIG. 2. In some embodiments, the heat pipe chamber 280 is vacuum sealed to extract better performance with vacuum pressure of about 0.05-0.5 Torr.

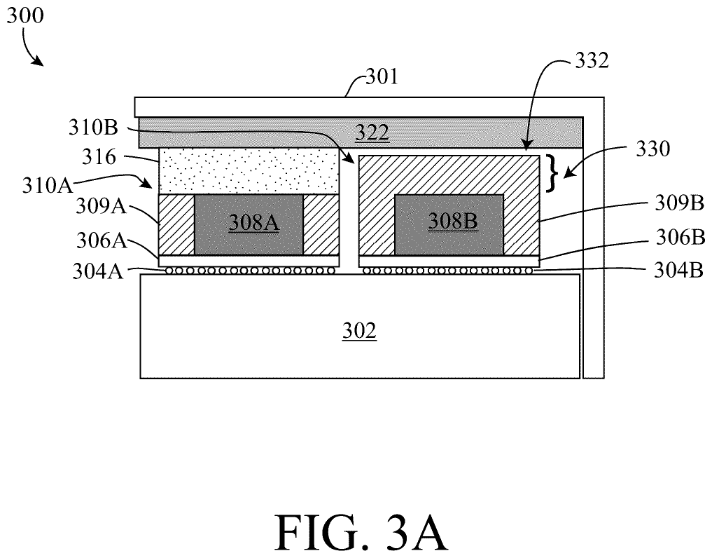

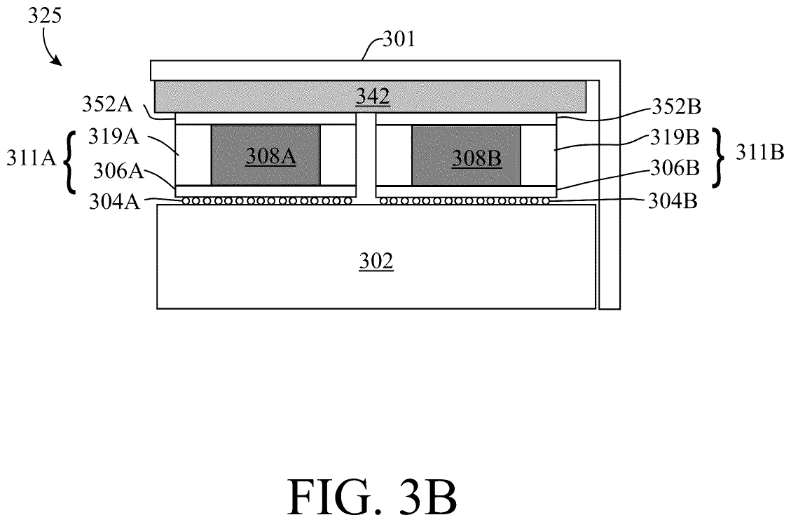

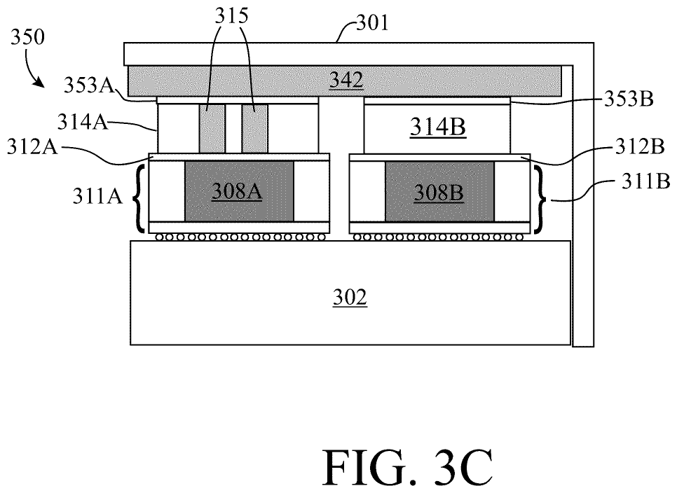

FIG. 3A shows illustrative schematic sectional side view of a portion of an example electronic device 300. The electronic device 300 may be a mobile device, a computing device, a handheld device, or similar. For example, the electronic device 300 may be a desktop, a laptop, a tablet, or a smartphone. The electronic device 300 includes a mother board 302 (e.g., main board).

One or more device packages may be attached to the mother board 302 via solder bumps 304A, 304B. For example, device packages 310A, 310B may include devices 308A, 308B on package substrates 306A, 306B, having molding compounds 309A, 309B. The device package 310A may have the molding compound 309A surrounding side surfaces of the device 308A. The device package 310B may have molding compound 309B surrounding top and side surfaces of the device 308B. The molding compounds 309A, 309B (e.g., mold compound) may comprise a polymer or an epoxy material. In some embodiments, the device packages 310A, 310B may comprise solder mount packages.

A cooling element 322 (e.g., heat spreader, pipe, or other element) may be disposed over the device packages (e.g., molding compounds 309A, 309B of the device package). The cooling element 322 may comprise a metal material or any other suitable material having high thermal conductivity. For example, the cooling element 322 may be a copper heat pipe or a copper heat spreader. The cooling element 322 may or may not be attached to the molding compounds 309A, 309B or solder mount package. For example, the device 308B and molding compound 309A may be attached to the cooling element 322 via TIM 316. The TIM 316 is between cooling element 322 and device 308B and the molding compound 309A surrounding the sides of device 308B. In another example, the cooling element 322 is in proximity to, but not in contact with the device package 310B. For example, there may be an air gap between the cooling element 322 and device package 310B. In some embodiments, the cooling element 322 may be in contact with the device package. In some embodiments, the cooling element 322 may be in contact with the device package 310A through a TIM layer 316. As another example, FIG. 1A shows the TIM 20 between the heat pipe 22 and the package device 10. The cooling element 322 may be attached to a casing 301 (e.g., phone case).

Heat energy from the device 308A is transferred through the molding compound 309A and/or the TIM 316 between the device 308A and the cooling element 322, with each such interface in the heat energy transfer chain presenting thermal resistance. For example, a thermal resistance may be between the device 308A and TIM 316, the TIM 316 has a thermal resistance, and another thermal resistance is between the TIM 316 and the cooling element 322. A thermal resistance may be between the device 308A and the molding compound 309A, and the mold compound 309A and TIM 316.

Heat energy from the device 308B is transferred through the molding compound 309B and the gap between molding compound 309B and the cooling element 322, with each such interface in the heat energy transfer chain presenting thermal resistance. For example, a first thermal resistance 330 is between the device 308B, and edge of the device package 310B, and second thermal resistance 332 is between the device package 310B and the cooling element 322.

A first heat spreader may surround the top and side surfaces of each device 308A, 308B and a TIM may be between the first heat spreader and a second heat spreader (e.g., cooling element 322) and a phone case (e.g., casing 301). For example, in FIG. 3A, the device packages 310A, 310B (package substrates 306A, 306B, devices 308A, 308B, and molding compounds 309A, 309B) and cooling element 322 may be replaced by the device package 10, the TIM 20, and the heat pipe 22 of FIG. 1A.

In FIG. 3A, the cooling element 322 is positioned above the molding compounds 309A, 309B or device packages 310A, 310B. The cooling element 322 may be positioned at a different location relative to the molding compounds 309A, 309B or device packages 310A, 310B.

The electronic device 300 may be a mobile device. The mobile device (e.g., mobile phone, tablet, laptop, etc.) may have a few watts of power (e.g., less than about tens of watts of power). The mobile device may comprise a high-performance processor generating heat, and thermal improvement may be desired. As functionality in a mobile device increases, the thermal management challenges may also increase. The space constraints in a mobile device may be tight. Conventional heat pipes or cooling systems may be limited due to the system level series thermal resistance. In mobile devices, metal covers or casings may be placed over the battery and device packages. The large surface area of metal covers or casings may make them suitable candidates for heat sinks for the space constrained mobile devices. The metal cover or casing may be attached to the phone without using thermal grease.

The mobile device may include heat spreaders attached to or above a processor (e.g., device, chip, or die) in the mobile device. For example, a heat spreader (e.g., cooling element 322) may be on top of a processor (e.g., device 308A). In some embodiments, the heat spreader may be attached to the processor (e.g., in contact with using a TIM, attached to a package device including the processor). In some embodiments, the heat spreader may be proximate to but not attached to the processor (e.g., above or adjacent to, without using thermal grease).

A heat pipe may be attached to the heat spreader (e.g., metal plate) using thermally conductive material. For example, as shown in FIG. 1A, the heat pipe 22 is attached to the heat spreader 18 using the TIM 20. In some embodiments, the heat spreader 18 may be connected to the heat pipe by soldering (e.g., solder) or a heat spreader pad. The heat pipe may be used as passive heat transfer from a package to elsewhere. The heat pipe may take the heat (e.g., hot air) extracted from the heat spreader on top of the processor to some other location (e.g., a frame or a fan or the casing which radiates the heat away due to a large surface area) to reduce the heat. For example, a first portion (e.g., hot end) of a heat pipe may be attached to a processor. The first portion of the heat pipe may be connected to the heat spreader on top of a processor via a TIM. Inside the heat pipe may be a wicking material (e.g., copper meshes, copper wires, copper or aluminum fibers, etc.). The cooling may occur in a second portion (e.g., cool end) of the heat pipe. The second portion of the heat pipe may be attached to a fan, a radiator, or another element.

The heat pipe may be a copper heat pipe. The inner wick lining inside the copper heat pipe may act as a capillary material for an amount (e.g., small amount) of fluid. As heat is applied to the heat pipe surface in an evaporator region (e.g., zone, section, e.g., first portion or hot end of the heat pipe), fluid may be heated and its phase changes from a fluid to vapor, creating pressure. The fluid may be more easily changed to a vapor under vacuum. As pressure increases, the vapor flows into the cooler section of the heat pipe (e.g., condensation zone, e.g., second portion of the heat pipe). The heat may then be released as the vapor condenses back into a fluid. The fluid is transported back to the warmer region via capillary action or wicking process, where the cycle repeats while heat is applied to that section (e.g., the evaporator region).

Thermal adhesive that attaches the heat pipe to the processor may limit the heat transfer due to additional thermal resistance of the adhesive and interface thermal resistance between the adhesive and heat pipe and processor. Adhesive or TIM is also prone to performance degradation over time. Thermal extraction from a chip directly by absorption media (e.g., liquid coolant, air jet, wicking media) without interference from a TIM may be more effective (e.g., compared to thermal extraction from a chip by absorption media with interference from a TIM).

In some embodiments, an integrated cooling assembly may involve a direct bond (e.g., direct dielectric bond or direct hybrid bond) between the device (e.g., semiconductor device, die, chip, or device package) and the cooling system. The cooling system may comprise an integrated heat spreader or integrated heat pipe. In some embodiments, the integrated heat spreader or integrated heat pipe may comprise dummy die(s). In some embodiments, the integrated heat spreader or heat pipe may comprise a flexible material structure (e.g., flexible structure). In some embodiments, the integrated heat spreader or heat pipe may comprise a heat pipe attached to a flexible material structure attached to a device (e.g., backside of a semiconductor device).

In some embodiments, an integrated cooling assembly may comprise a semiconductor device attached to a cooling element. The cooling element may be a heat spreader or a heat pipe. The cooling element may comprise a polyimide material or polyimide material with metal particulates, graphene, or carbon to increase the thermal conductivity of the polyimide material. The cooling element may comprise a high-temperature polymer material with conductive particulates. The cooling element may be a heat pipe, and a copper material layer with a porous dendritic structure on an inside surface of the heat pipe. Dummy chiplets may be attached to the heat pipe and a heat sink using conductive paste (e.g., TIM). The heat sink may be a backplane of a mobile device. Heat from the device may be transferred directly to the heat pipe. Heat from the shell of the heat pipe may be transferred to the heat sink through the dummy chiplets.

FIGS. 3B-3C show an illustrative schematic sectional side view of examples of portions of electronic devices. FIGS. 3B and 3C show illustrative schematic sectional side view of a portion of example electronic devices 325, 350. The electronic devices 325, 350 may include similar features to the example electronic device 300, and therefore the description of similar features is omitted for brevity. FIG. 3B shows a cooling element 342 attached to a backside of devices 308A, 308B. FIG. 3C shows a cooling element 342 attached a flexible material structure (e.g., comprising organic materials 314A, 314B) attached to the backside of the devices 308A, 308B.

In FIGS. 3B-3C, molding compounds 319A, 319B may be similar to the molding compounds 309A, 309B of FIG. 3A, except the molding compounds 319A, 319B are not on a backside of the devices 308A, 308B and the devices 308A, 308B are exposed through the molding compounds 319A, 319B. The cooling element 342 (e.g., heat pipe, heat spreader, etc.) may comprise a flexible material (e.g., organic material, composite material comprising organic material and thermally conductive particulates).

In some embodiments, the cooling element 342 comprises an organic material or a composite material. For example, the organic material may be a polymer (e.g., high temperature polymer material, polyimide (PI), polybenzoxazoles (PBO), etc.). The composite material may comprise an organic material and particulates (e.g., PI and metal particulates, graphene, M+, or other). The particulates may be thermally conductive particulates (e.g., metal particulates, graphene, graphene composite, M+, and/or Cu).

As shown in FIG. 3B, the cooling element 342 may be attached to the devices 308A, 308B. For example, the cooling element 342 may be attached to the devices 308A, 308B using thermal adhesives, thermal pastes, TIMs or through direct bonding (e.g., direct dielectric bonds or hybrid bonds). In some embodiments, such as the one shown in FIG. 3B or any other embodiment of the disclosure, the adhesive may be a compliant adhesive which may expand and contract, or may be flexible and move, when the heat pipe expands and contracts under heating and cooling. This may prevent damage to the device and may also prevent the cooling element from separating from the device. The adhesive may be such that it mitigates any mismatch in coefficient of thermal expansion between the device and the cooling element. The adhesive may include solder.

In some embodiments, the cooling element 342 may be attached to the devices 308A, 308B by direct bonding. For example, a region of the cooling element 342 may be coated with a dielectric layer, and directly bonded to the devices 308A, 308B. In some embodiments, a dielectric layer may comprise native dielectric layer (e.g., native oxide), a deposited dielectric layer (e.g., deposited oxide, nitride, carbonitride, etc.), or any suitable dielectric layer such as those mentioned above in this disclosure. In some embodiments, the devices 308A, 308B may comprise a substrate with one or more dielectric layers. In some embodiments, the devices 308A, 308B may comprise a native dielectric layer (e.g., native oxide) or a deposited dielectric layer (e.g., deposited oxide) on a substrate (e.g., silicon). For example, the devices 308A, 308B may comprise silicon bulk material with a silicon nitride and/or silicon oxide layer. Attaching the cooling element 342 to the devices 308A, 308B may comprise directly bonding a dielectric layer disposed on the cooling element 342 to a backside of the devices 308A, 308B to form direct dielectric bonds 352A, 352B. In some embodiments, the dielectric layer may further include conductive features. In some embodiments, the backside of the devices 308A, 308B may further include conductive features, and the cooling element 342 may be attached to the backside of the devices 308A, 308B using hybrid bonds.

As shown in FIG. 3C, the cooling element 342 may be attached to a flexible material structures 314A, 314B attached to the devices 308A, 308B. For example, the cooling element 342 may be attached to the flexible material structures 314A, 314B using adhesive or through direct bonding (e.g., direct dielectric bonds or hybrid bonds). The flexible material structures 314A, 314B may be attached to the devices 308A, 308B using adhesive or through direct bonding (e.g., direct dielectric bonds or hybrid bonds).

In some embodiments, the cooling element 342 may be attached to the flexible material structures 314A, 314B by direct bonding. For example, a region of the cooling element 342 may be coated with a dielectric layer, and directly bonded to the flexible material structures 314A, 314B to form direct dielectric bonds 353A, 353B. In some embodiments, the flexible material structures 314A, 314B may further include conductive features, and the cooling element may be attached to the flexible material structures 314A, 314B using hybrid bonds.

In some embodiments, the flexible material structures 314A, 314B may be attached to the devices 308A, 308B (or device packages 311A, 311B) by direct bonding. For example, a region of the flexible material structures 314A, 314B may be coated with a dielectric layer, and directly bonded to a backside of the devices 308A, 308B (or device packages 311A, 311B) to form direct dielectric bonds 312A, 312B. In some embodiments, the backside of the devices 308A, 308B may further include conductive features, and the flexible material structures 314A, 314B may be attached to the backside of the devices 308A, 308B using hybrid bonds.

The flexible material structures 314A, 314B may comprise a flexible material. The flexible material may be an organic material or a composite material, e.g., as described above in relation to the cooling element 342. In some embodiments, vias 315 are formed through the flexible material.

In some embodiments, the flexible material structure 314A may comprise a first dielectric layer, a flexible material layer, and a second dielectric layer. In some embodiments, the first dielectric layer and may be a flexible substrate, where the flexible material layer is disposed on the flexible substrate and the second dielectric layer is disposed on the flexible material layer. In some embodiments, the first dielectric layer may comprise one or more dielectric layers. In some embodiments, the second dielectric layer may comprise one or more dielectric layers. In some embodiments, the one or more dielectric layers may be inorganic dielectric layers (e.g., a silicon nitride and/or silicon oxide layer) disposed on a flexible material layer. In some embodiments, the first dielectric layer and/or the second dielectric layer may further include conductive features disposed in a respective dielectric layer.

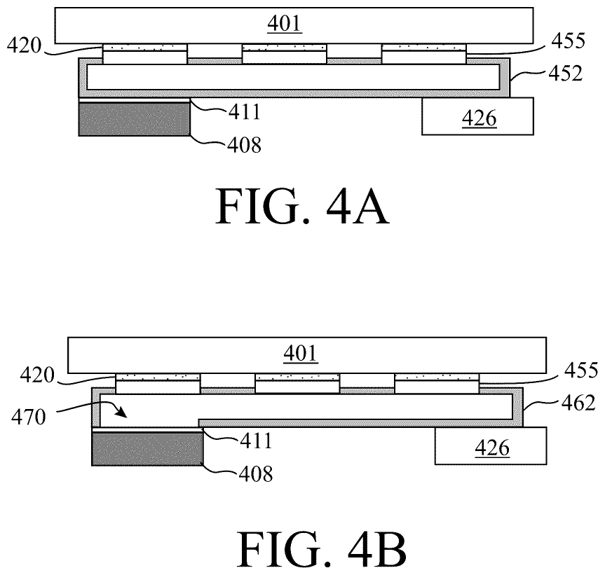

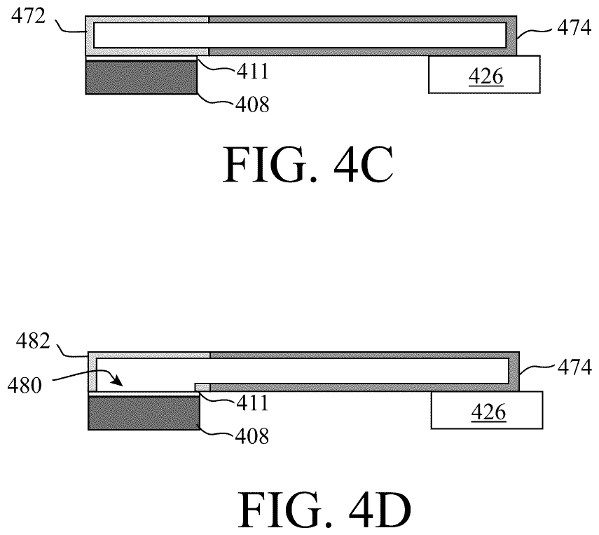

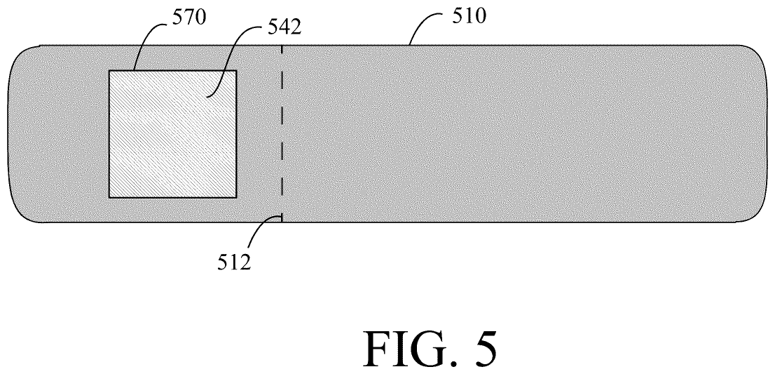

The cooling element 342 may be a heat spreader or heat pipe comprising a flexible material (e.g., organic material, composite material). In some embodiments, an inorganic dielectric may be deposited on the flexible material to bond the cooling element 342 to the devices 308A, 308B. In some embodiments, the cooling element 342 may be vacuum sealed, and the cooling element 342 may be directly bonded to the devices 308A, 308B. In some embodiments, portions of the cooling element 342 may be attached to the devices 308A, 308B (e.g., via adhesive, glue, or direct bonding without intervening adhesive). In some embodiments, the back of the devices 308A, 308B may be exposed to an internal portion of a heat pipe (e.g., as described in relation to FIGS. 4B, 4D, and 5).

In some embodiments, conductive pads or thermal vias may be soldered to the cooling element 342. For example, the flexible material structures 314A, 314B may comprise conductive features or metal vias. The flexible material structures 314A, 314B may include an oxide and/or nitride layer to be DBI bonded. The flexible material structures 314A, 314B may comprise copper wire(s) or conductive feature(s) disposed in an organic material. In some embodiments, chips may be attached to an organic material.

The organic material layer may comprise an organic material or a composite material. The organic material layer may comprise a low stress polymer (e.g., polyimide, PBO, etc.) film or layer. The composite material may comprise an organic material and particulates. The particulates may be thermally conductive particulates. The thermal conductivity of the composite material may be improved (e.g., greater than) the thermal conductivity of the organic material. The particulates may be added to the organic material to create a reinforced material. The flexible material structures 314A, 314B may be attached to a heat pipe or a heat spreader using adhesive or direct bonding (e.g., with direct dielectric bonds or direct hybrid bonds).

The flexible material structures 314A, 314B may comprise an organic material layer (e.g., polymer layer, low stress polymer film such as polyimide, PBO, etc.) and one or more dielectric layers (e.g., SiN or SiO₂ material layers). For example, the one or more dielectric layers may comprise an adhesion layer and a bonding layer. A silicon nitride layer may be used as an adhesion layer to the organic material. A silicon oxide layer may be used as a bonding layer (e.g., to a dielectric layer on a region of a heat pipe or a heat spreader).

The flexible material structures 314A, 314B may comprise a metal layer (e.g., metal fill layer, aluminum). For example, a metal layer may be embedded in an organic layer or composite layer. The metal layer may reduce stress and improve dielectric adhesion.

The flexible material structures 314A, 314B may comprise a metal via. For example, the flexible material structures 314A, 314B may comprise one or more dielectric layers, an organic or composite layer, and one or more metal vias 315. The one or more metal vias 315 may be a metal feature extending through the one or more dielectric layers and the organic or composite layer 314A.

In some embodiments, conductive features or bond pads may be incorporated into the flexible material structure. For example, a conductive feature (e.g., comprising metal material) may be deposited in a polymer layer.

In some embodiments, the flexible material structures 314A, 314B enable direct dielectric or hybrid bonding to semiconductor devices with different heights. In some embodiments, the devices 308A, 308B may comprise a first device and a second device with different thicknesses, and the thickness of a corresponding flexible material structures 314A, 314B may be of different thicknesses.

In some embodiments, a flexible material structure may refer to a flexible structure, flexible section, or flexible unit, for example, described in U.S. Provisional 63/293,299, filed Dec. 23, 2021, U.S. application Ser. No. 18/145,747, filed Dec. 22, 2022, or US Patent Application Pub. No. 2023/0207474, published Jun. 29, 2023, the disclosures of each of which is incorporated by reference herein in its entirety.

The flexible material structure (e.g., flexible unit) can have a Young's modulus in a range of 2 GPa to 15 GPa, e.g., in a range of 2 GPa to 12 Gpa. In some embodiments, the flexible unit may comprise a composite material including an organic material with particles or chopped fiber to create a reinforced material. In the illustrated embodiments, the flexible unit can be bendable without breaking an insulating base layer and without disrupting electrical connectivity of conductive traces. The flexible unit may remain bendable in a bonded structure or may be fixed so as to be unbendable in a bonded structure (e.g., if the bonded structure is overmolded). The flexible unit can be considered a flexible material even though it may be rendered inflexible in a surrounding material, such as a molding compound. The flexible unit may be directly bonded to semiconductor devices with different heights.

The flexible material structure may comprise an insulating substrate. The insulating substrate can comprise an insulating base layer and conductive layers or features disposed in the insulating base layer. In some embodiments, the insulating base layer comprises a flexible thickness of an organic material. For example, the organic material can comprise a polymer, such as at least one of a liquid crystal polymer (LCP) and a polyimide. A coefficient of thermal expansion (CTE) of the organic layer can be less than 10 ppm/° C. In other embodiments, the insulating base layer can comprise a flexible thickness of an inorganic material.

FIGS. 4A-4D show an illustrative schematic sectional side view of examples of a cooling assembly. The cooling assembly comprises a heat pipe attached to a device 408. The heat pipe may be attached to the device 408 using adhesive or direct bonding. The thickness of the heat pipe may be about 0.5 mm or more. The heat pipe shown in FIGS. 4A-4D and heat pipes in various embodiments of the present disclosure may have a similar structure to the heat pipe 222 as shown in FIG. 2. For example, the heat pipe shown in FIGS. 4A-4D and heat pipes in various embodiments of the present disclosure may include wicking media inside the heat pipe. However, while the heat pipe 222 may be a metal heat pipe, at least a portion of the heat pipe shown in FIGS. 4A-4D comprises a flexible material which is attached to the device 408.

FIG. 4A shows a heat pipe 452 comprising a flexible material. The heat pipe 452 may correspond to the cooling element 342 of FIG. 3C. For example, the flexible material may be a non-metal material, an organic material, or a composite material comprising an organic material and particulates, such as those described above in relation to cooling element 342. The heat pipe 452 may comprise a polymer material (e.g., polyimide (PI), polybenzoxazoles (PBO), etc.). In some embodiments, the heat pipe 452 may comprise a composite material (e.g., polymer material and particulates). For example, the composite material may comprise a PI graphene composite, or PI M+ composite, or PI Cu composite. The particulates may be thermally conductive particles. For example, the particulates may be metal, graphene, or carbon.

FIG. 4B shows a heat pipe 462 that is similar to the heat pipe 452, except that the heat pipe 462 has an opening to expose a backside of the device 408 to the cooling or wicking media of the heat pipe 462. The opening may be circular, oval, elliptical, hexagonal, square or rectangular shaped, or any other regular or irregular shape.

In FIGS. 4A and 4B, heat may get extracted in a cold portion. For example, the cold portion may correspond to a portion of the heat pipe attached to a heat sink 426. Some heat may get extracted in other portions of the heat pipe (e.g., regions attached to a casing via dummy chiplets). In some embodiments, thermal conductivity may be improved. The cooling media may be in direct contact with the device 408, or close to the device 408 with little or no thermal resistance. For example, the heat pipe 452 or the heat pipe 462 may be directly bonded to the device 408. For example, an interface element 411 may comprise a dielectric layer (e.g., inorganic dielectric layer, oxide, nitride) disposed in a region on an outer surface of the heat pipe 452 and attached to a backside of the device 408 (e.g., dielectric layer on silicon) via direct dielectric bonds. In some embodiments, the interface element 411 may comprise a flexible material structure. In some embodiments, instead of a continuous layer over the device 408, the interface element 411 may be disposed only on portions of the flexible material of the heat pipe 462 (e.g., portions in contact with the device 408 and not underneath the openings 470). In some embodiments, the interface element 411 may be an adhesive. An internal surface of the heat pipe 452 or 462 may be covered with wicking material, and the wicking material may be directly exposed to the back of the device 408 and there may be no thermal interface materials.

In some embodiments, one or more dummy thermal chiplet dies 455 may be attached to the heat pipe 452 or 462 (e.g., as shown in FIGS. 4A and 4B) via thermal interface material or TIM 420. A dummy thermal chiplet die may be a dummy semiconductor chip or die (e.g., semiconductor wafer diced into chips or dies). In some embodiments, one or more conductive pads may be attached to a heat pipe. For example, some portions of the heat pipe may have chips or conductive pads (e.g., copper pads) so as heat gets transferred to steam in the heat pipe, heat may get transferred to chips (e.g., dummy chiplets) or conductive pads, to the backplate or casing 401 of the electronic device. In some embodiments, the heat pipe 452 is attached to the backplate or casing 401 of the electronic device via TIM without any dummy thermal chiplet. The backplate or casing 401 may act as a heat sink for dummy chiplets. The heat pipe 452 or 462 comprising a flexible material (e.g., organic or composite material) with a chip may extract heat directly without TIM, and may provide a compliant structure. For example, one or more chiplets may enable heat to be extracted from the body of the heat pipe. Polymer material (e.g., PI) may allow for flexibility. The one or more chiplets or conductive pads may improve the thermal conductivity because PI may have low thermal conductivity. In some embodiments, one or more dummy chiplets may be directly in contact with the cooling or wicking media of the heat pipe 452 via one or more openings (similar to opening 470) in the heat pipe 452. In some embodiments, side surfaces of dummy chiplets 455 may attached to side surfaces of portions of the heat pipe 452 using adhesive, direct dielectric bonds, or hybrid bonds. For example, the side surfaces of the dummy chiplets 455 may be attached to side surfaces of portions of the heat pipe using adhesive or TIM layer. For example, the side surfaces of the dummy chiplets 455 may be directly or hybrid bonded to side surfaces of the heat pipe, each comprising a dielectric layer or conductive features disposed in the dielectric layer. In some embodiments, the wicking media inside the heat pipe 452 is exposed via one or more openings (similar to opening 470) in the heat pipe and then attached to the backplate or casing 401 of the electronic device via TIM without any dummy thermal chiplet in between the wicking media and casing 401.

In some embodiments, the CTE mismatch between a copper heat pipe and the chip may adversely affect the package, so a heat pipe comprising a flexible material may be directly bonded to the chip. In some examples, a flexible heat pipe may be directly bonded to the chip (e.g., as shown in FIGS. 4A and 4B). In other examples, a flexible heat pipe portion may be bonded to the chip. For example, a heat pipe may comprise a flexible heat pipe portion attached to a copper heat pipe portion, as shown in FIGS. 4C and 4D.

FIGS. 4C and 4D show the heat pipe comprising a flexible portion 472 (e.g., comprising organic material) joined to a metal portion 474. In FIGS. 4C and 4D, the heat may get extracted in a cold portion. For example, the cold portion may correspond to a portion of the heat pipe attached to a heat sink 426. In some embodiment, the cold portion may be the backplate or casing 401 of the electronic device. In some embodiments, the metal portion 474 may be a portion of a copper heat pipe. The flexible portion 472 may comprise flexible material, as described above in relation to the heat pipe 452. In some embodiments, the flexible portion 472 or 482 of the heat pipe may be similar to a portion of the heat pipe 452 or 462. The cooling media or wicking media inside the heat pipe may be in direct contact with the device 408, or close to the device 408 with little or no thermal resistance. For example, the flexible portion 472 or 482 of the heat pipe may be directly bonded to the device 408. For example, the interface element 411 may comprise a dielectric layer (e.g., inorganic dielectric layer, oxide, nitride) disposed in a region on an outer surface of the flexible portion 472 or 482 of the heat pipe and attached to a backside of the device 408 (e.g., dielectric layer on silicon) via direct dielectric bonds. In some embodiments, the interface element 411 may comprise a flexible material structure. In some embodiments, instead of a continuous layer over the device 408, the interface element 411 may be disposed only on portions of the flexible portion 472 or 482 of the heat pipe (e.g., portions in contact with the device 408). In some embodiments, the interface element 411 may be an adhesive. An internal surface of the heat pipe comprising the flexible portion 482 and the metal portion 474, or the heat pipe comprising the flexible portion 482 and the metal portion 474 may be covered with the wicking material, which may be directly exposed to the back of the device 408. There may be no thermal interface materials.

Heat transfer from the flexible portion 472 (e.g., made of PI material, high temperature polymer material with thermally conductive particulates) of the heat pipe to the metal portion 474 of the heat pipe may be via a PI/Cu joint/seal (and wicking material interface). The PI/Cu joint may be made of adhesive, glue, or solder. the flexible portion 472 (e.g., first portion) of the heat pipe may be made of polymer, and the metal portion 474 (e.g., second portion) of the heat pipe may be made of copper material. The internal of the heat pipe may be continuous coverage of a wicking media. The wicking media may cover the backside of the device 408. The wicking media may be a copper layer with a porous dendritic structure for condensation. The wicking media may be formed with a metal seed layer and pitted dendritic metal that is porous. For example, the wicking media may be formed with a copper seed layer and pitted dendritic copper that is porous. The flexible portion 472 of the heat pipe may be joined to the device 408 by direct bonding or hybrid bonding to a backside of the device 408. In some embodiments, the wicking media inside the flexible portion 472 of the heat pipe is exposed to the backside of the device 408 via one or more openings (similar to opening 470) in the flexible portion 472. In some embodiments, the flexible portion 472 is attached to the backside of the device 408 via a ring of the adhesive material (e.g., glue) at the periphery of the openings in the flexible portion 472 and the wicking media is in direct contact with the backside of the device 408 through the opening.

FIG. 5 shows a heat pipe having an opening 570 cut therein, and in the example shown in FIG. 5, the opening 570 is square. The opening 570 may be circular, oval, elliptical, hexagonal, square or rectangular shaped, or any other regular or irregular shape. In some embodiments, the heat pipe can have more than one such opening 570. Through the opening 570, wicking material 542 inside the heat pipe 510 can be seen. In some embodiments, the opening 570 in FIG. 5 corresponds to the opening 470 of FIG. 4B and opening 480 of FIG. 4D. In some embodiments, the wicking material 542 may be similar to the wicking material 242 described above, and therefore the description of similar features is omitted for brevity.

In some embodiments, the heat pipe 510 corresponds to the heat pipe 462 shown in FIG. 4B. In some embodiments, the heat pipe 510 corresponds to the heat pipe shown in FIG. 4D. In some embodiments, a dotted line 512 separates the heat pipe 510 into a first portion (left) and a second portion (right), where the first portion comprises organic or composite material and the second portion comprises a metal material or any other suitable material having high thermal conductivity.

In some embodiments, the device wicking material 542 can be a dendritic metal (e.g., copper or copper alloy) material formed on the backside of the device that the heat pipe 510 is attached to. For example, the device wicking material 542 can be a dendritic copper material formed on the backside of the device that the heat pipe 510 is attached to. This dendritic copper material may be a porous copper dendritic film. In some examples, copper or metallic dendrites may be grown on the backside of the device at a wafer level. Such copper or metallic dendrites may be porous or rough, and may be porous copper or rough copper, and may be grown on the backside of the device of the device package. In some examples, an adhesive may be applied after the dendritic copper is grown or placed on the backside of the device. In some embodiments, the device wicking material or wicking media may include dendritic copper, copper mesh, copper wires, etc.

When heat extraction is concerned, a material with higher thermal conductivity may be preferred (e.g., for a heat pipe or a heat spreader). When thermal conductivity of a material is less than about 0.1 W/mK, a material may be similar to a thermal insulator. Thermal resistance may decrease rapidly with the increase in thermal conductivity. A thermal conductivity of copper may be better than silicon. A thermal conductivity of polyimide may be lower than silicon. A thermal conductivity of polyimide may be improved with thermally conductive or metal particulates, but may still have lower thermal conductivity than both copper and silicon. In some embodiments, the thermally conductive or metal particulates may be graphene, carbon, copper, Cu/C or graphene/Cu composite.

In some embodiments, a heat pipe or heat spreader is comprised of a material having less than about 0.1 W/mK, 0.12 W/mK, 0.13 W/mK, 0.14 W/mK, 0.15 W/mK, 0.2 W/mK, 0.4 W/mK, 0.8 W/mK, or 1 W/mK in thermal conductivity. In some embodiments, a heat pipe or heat spreader is comprised of a material having more than about 0.1 W/mK, 0.12 W/mK, 0.13 W/mK, 0.14 W/mK, 0.15 W/mK, 0.2 W/mK, 0.4 W/mK, 0.8 W/mK, or 1 W/mK in thermal conductivity.

The heat pipe may be made of polyimide, to enable flexibility. Flexibility may be desired when connecting to devices of different heights that are spread out. A polyimide heat pipe may have better flexibility over a copper heat pipe.

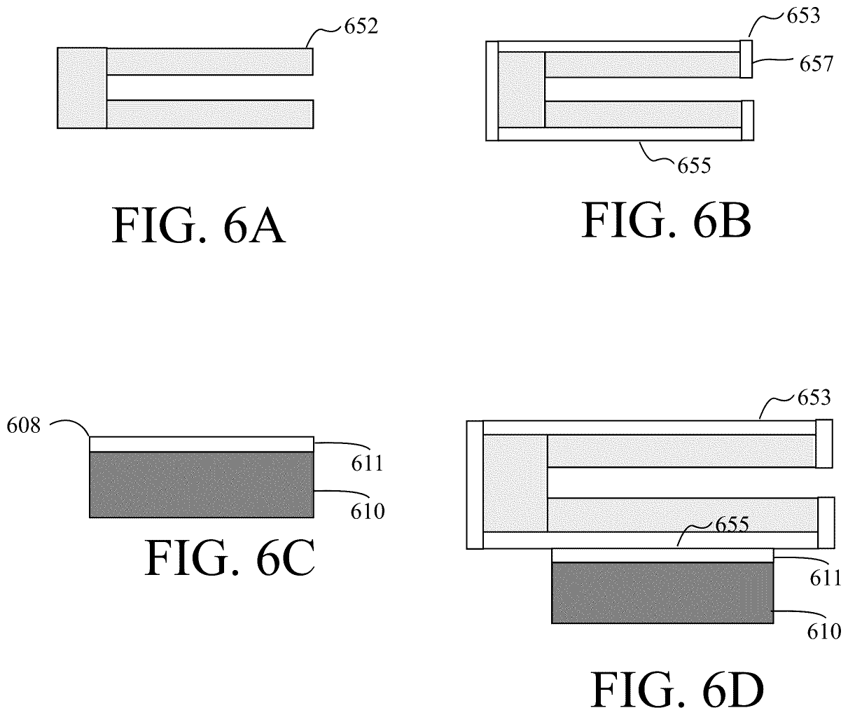

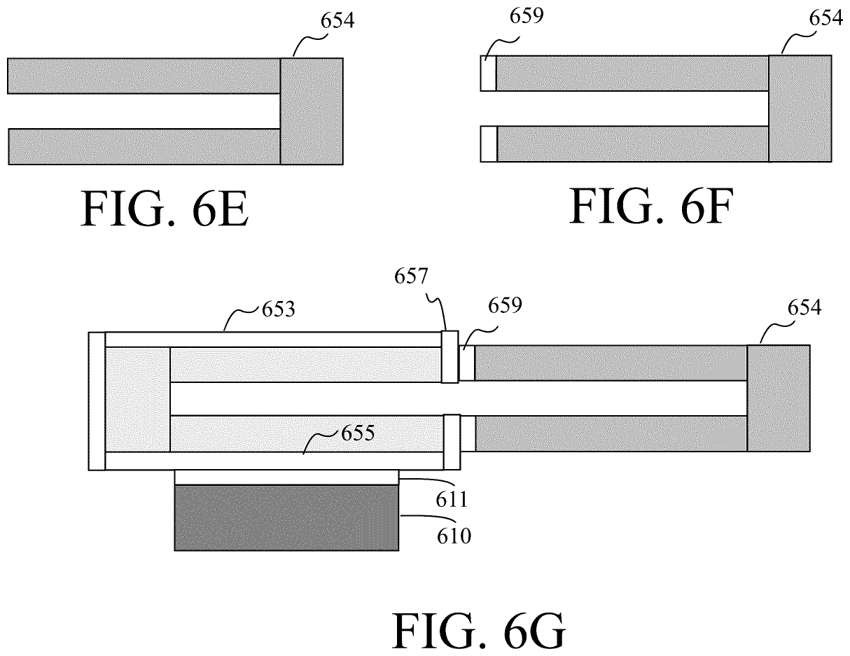

FIGS. 6A-6G illustrate schematic sectional side views of examples of forming a cooling assembly at different stages of manufacturing. In some embodiments, FIGS. 6A-6G illustrate an assembly flow for attaching a heat pipe to a device and forming a heat pipe by attaching a first portion of the heat pipe to a second portion of the heat pipe.

FIG. 6A may show a first portion 652 of the heat pipe fabrication. In some embodiments, the first portion 652 may be similar to the flexible portion 472 or the flexible portion 482 of the heat pipe. In some embodiments, the first portion 652 may have an opening cut therein (e.g., portion of heat pipe in FIG. 5 with opening 570). In some embodiments, the first portion may be the flexible portion 472, the flexible portion 482, a non-metal portion, or a portion comprising organic or composite material of the heat pipe. The first portion 652 of the heat pipe may be formed with polyimide formation techniques, applying temperature and pressure, with a spacer. Although FIG. 6A may refer to polyimide or using polyimide formation techniques, any suitable flexible material (e.g., polymer, high temperature polymer, etc.) and formation techniques may be used.

FIG. 6B may show a dielectric layer 653 is deposited on the outside surfaces of the first portion 652 of the heat pipe. The dielectric layer 653 may be deposited through plasma enhanced chemical vapor deposition or molecular vapor deposition which allows bonding to organics with silane on one end to oxidize and form a dielectric layer (e.g., thin dielectric layer).

FIG. 6C may show a device 608 comprising a silicon substrate 610 and a dielectric layer 611. In some embodiments, the dielectric layer 611 may comprise one or more dielectric layers.

FIG. 6D may show attaching the first portion 652 of the heat pipe to the device 608. The first portion 652 of the heat pipe may comprise an organic or composite material. Surfaces of a region of the dielectric layer 655 and the dielectric layer 611 may be chemically activated and brought in contact with each other. In some embodiments, preparing a surface or substrate for direct or hybrid bonding such as activating a surface may be performed in any suitable manner, for example, as described above in this disclosure. In some embodiments, a room temperature bonding or bonding at ambient temperature may occur to form a workpiece. In some embodiments, the workpiece may be heated (e.g., to a temperature between about 50° C. to about 150° C.). In some embodiments, a bottom surface of the heat pipe structure shown in FIG. 6B may be attached to a top surface of the device 608.

FIG. 6E may show a second portion 654 of the heat pipe. The second portion 654 of the heat pipe may comprise a metal material or any other suitable material having high thermal conductivity.

FIG. 6F shows a formation of a dielectric layer 659 at a region of the second portion 654 of the heat pipe which may be used to generate direct dielectric bonds. In some embodiments, the dielectric layer 659 oxidizes. In some embodiments, the dielectric layer may be formed by oxidation. In some embodiments, the dielectric layer 659 is deposited. For example, an oxide layer (e.g., thin oxide layer) is deposited.

FIG. 6G may show attaching the first portion 652 of the heat pipe to the second portion 654 of the heat pipe. The first portion 652 of the heat pipe may be attached to the second portion 654 of the heat pipe using adhesive or direct bonding. In some embodiments, the first portion 652 of the heat pipe may be attached to the second portion 654 of the heat pipe (e.g., metal heat spreader) as shown in FIG. 6G using direct bonding. For example, a dielectric layer 657 at a region on the first portion of the heat pipe is directly bonded to the dielectric layer 659 on a region of the second portion of the heat pipe, forming direct dielectric bonds. In some embodiments, the dielectric layers 657 and 659 may be polished before direct bonding. In some embodiments, adhesive glue or sealant may be used to attach the first portion 652 to the second portion 654 of the heat pipe.

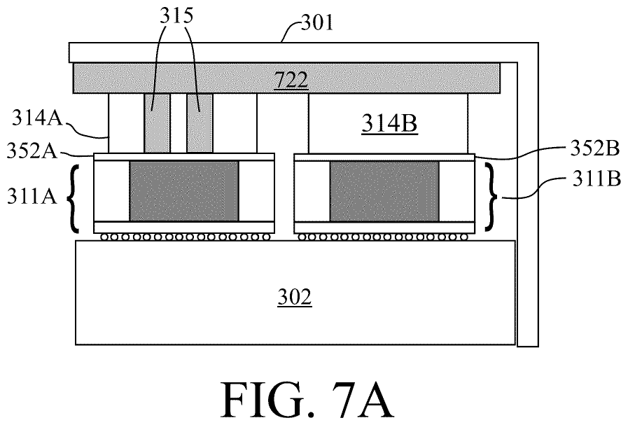

FIGS. 7A-7B illustrate schematic sectional side views of examples of an electronic device. In FIGS. 7A-7B, the cooling element 722 comprises a metal material or any other suitable material having high thermal conductivity (e.g., metal heat pipe or metal heat spreader). In some embodiments, the flexible material structure 314A, may have vias 315 (e.g., thermal vias, copper vias) to extract the heat from the back of the devices 308A, 308B to the cooling element 722 (e.g., heat pipe or heat spreader).

In FIG. 7A, the flexible material structures 314A, 314B (e.g., with or without vias 315) may attached to the cooling element 722 with solder or adhesive. In FIGS. 7A-7B, the flexible material structures 314A, 314B with or without vias 315 may be attached to the device package 311A (e.g., devices 308A, 308B and molding compounds 319A, 319B) using direct bonding. In FIG. 7B, the flexible material structures 314A, 314B with or without vias 315 may be attached to the cooling element 722 using direct bonding. In some embodiments, in FIGS. 7A-7B, and in any other figures of the present disclosure, one or more oxide, nitride, and/or any suitable dielectric layer (e.g., as mentioned above in this disclosure) may be used or deposited to facilitate direct bonding.

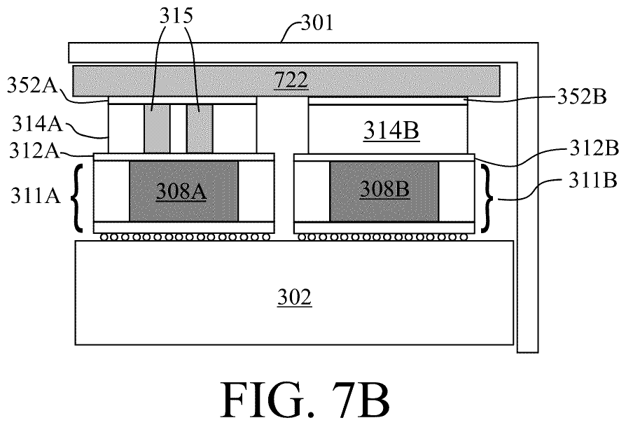

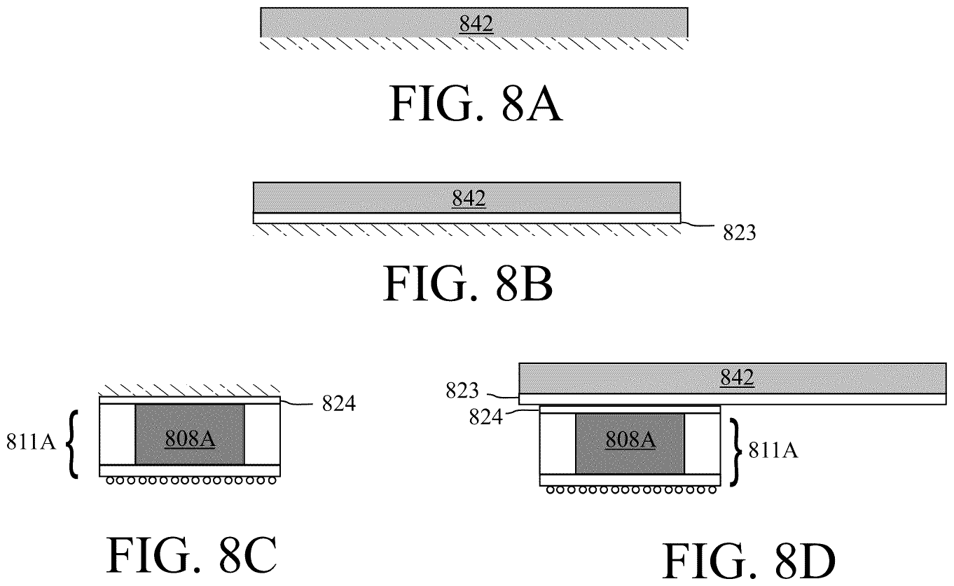

FIGS. 8A-8D illustrate schematic sectional side views of examples of forming a cooling assembly at different stages of manufacturing. FIGS. 8A-8D may show a method of directly bonding the device 808A (e.g., device package 811A) to the cooling element 842 (e.g., heat pipe or heat spreader). In some embodiments, the device package 811A is similar to device package 311A. In some embodiments, the cooling element 842 is similar to the cooling element 342. The cooling element 842 may comprise a flexible material (e.g., organic material or composite material). The method may include chemically activating both parts or surfaces to be joined (e.g., using plasma or wet chemistry). The method may include bonding the parts at room temperature with pick and place. The method may include annealing at a temperature about 50 to 200° C., or as low as about 100° C. for a duration (e.g., short time) to achieve bond strength (e.g., high bond strength).

FIG. 8A may show activation of a surface of the cooling element 842. FIG. 8B may show a dielectric layer 823 being deposited on the activated surface of the cooling element 842, and activating the dielectric layer 823. FIG. 8C may show activation of an interface layer 824 (e.g., SiₓO_{y}N_{z}C material) on the device package 811A. The dielectric layer 823 and interface layer 824 may each comprise a plurality of layers. FIG. 8D may show attaching the device 808A (or device package 811A) to the cooling element 842 by directly bonding the dielectric layer 823 to the interface layer 824.

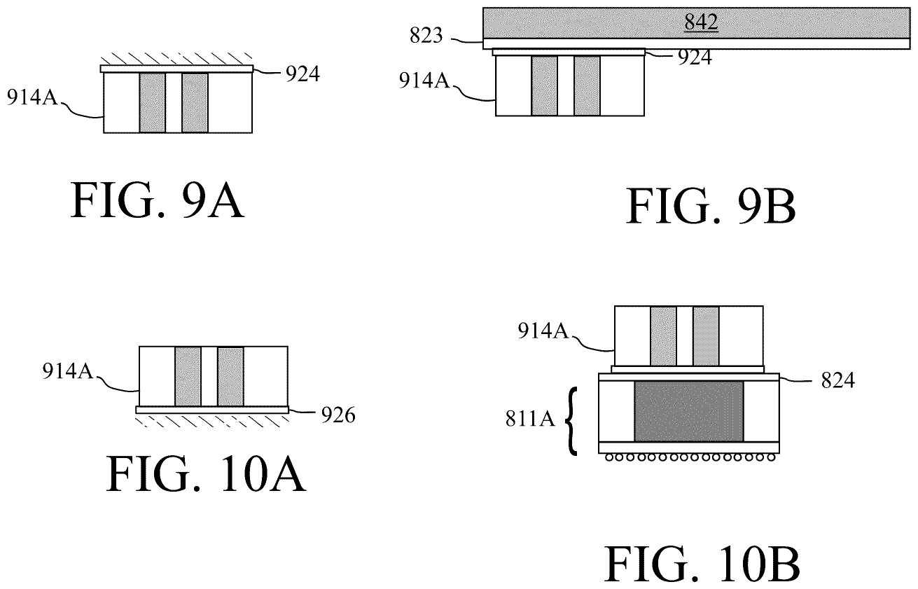

FIGS. 9A-9B illustrate schematic sectional side views of examples of forming a cooling assembly at different stages of manufacturing. FIG. 9A shows a dielectric layer 924 disposed on a flexible material structure 914A, and activation of a surface of the dielectric layer 924. In some embodiments, the flexible material structure 914A may be similar to the flexible material structure 314A.

FIG. 9B shows the cooling element 842 and the dielectric layer 823 of FIG. 8B being bonded to the flexible material structure 914A and the dielectric layer 924 of FIG. 9B.

FIGS. 10A-10B illustrate schematic sectional side views of examples of forming a cooling assembly at different stages of manufacturing. FIG. 10A shows a dielectric layer 926 and a flexible material structure 914A. A surface of the dielectric layer 926 is activated.

FIG. 10B shows the package device 811A and the dielectric layer 824 of FIG. 8C being bonded to the dielectric layer 926 and the flexible material structure 914A of FIG. 10A.

In some embodiments, a heat pipe (or cooling element, heat spreader, etc.) and a backside of a device as described in various embodiments of the disclosure may be in direct contact. For example, the heat pipe may be in direct contact with the backside of the device. In some embodiments, one or both of the heat pipe and the backside of the device may comprise a dielectric material layer, e.g., a first dielectric material layer and a second dielectric material layer respectively, and the heat pipe is directly bonded to the backside of the device through bonds formed between the dielectric material layers. In some embodiments, one of the heat pipe or the backside of the device may comprise a thin bonding dielectric layer (e.g., silicon nitride, etc.) and other element(s) may not include any such explicit bonding dielectric layer (or can have only native oxide layer). Here, the first and second dielectric material layers may be continuous layers, but it will be understood that one or both of the layers may not be continuous. For example, the first dielectric material layer may be disposed only on lower surfaces of the heat pipe facing the backside of the device package. Beneficially, directly bonding the heat pipe to the device, as described above, reduces the thermal resistance therebetween and increases the efficiency of heat transfer from the device to the heat pipe.

In some embodiments, the heat pipe may be attached to the device using a hybrid bonding technique, where bonds are formed between the dielectric material layers and between metal features, such as between the first metal pads and second metal pads, disposed in the dielectric material layers.

Suitable dielectrics that may be used as the dielectric material layers include silicon oxides, silicon nitrides, silicon oxynitrides, silicon carbon nitrides, metal-oxides, metal-nitrides, silicon carbide, silicon oxycarbides, silicon oxycarbonitride, diamond, diamond-like carbon (DLC), or combinations thereof. In some embodiments, one or both of the dielectric material layers are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, or 100 nm or more. In some embodiments, one or both of the layers are deposited to a thickness of 3 micrometer or less, 1 micrometer or less, 500 nm or less, such as 100 nm or less, or 50 nm or less. The dielectric layer material and thickness may be optimized for lower thermal resistance between the device package and the heat pipe.

If the heat pipe is attached to the device by direct bonding, this may include forming dielectric layers on one or both the of the heat pipe which may be a first substrate and the device 408 which may be a second substrate, and directly bonding includes forming dielectric bonds between a first dielectric material layer of the first substrate and a second dielectric material layer of the second substrate (or forming dielectric bonds between one substrate and a dielectric material layer of the other substrate). Direct bonding processes join dielectric layers by forming strong chemical bonds (e.g., covalent bonds) between the dielectric layers.

Generally, directly bonding the surfaces (of the dielectric material layers formed on the first and second substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the first and second substrates using a CMP process. Activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, some embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces.

In some embodiments, the plasma is formed using a nitrogen-containing gas, e.g., N2, and the terminating species includes nitrogen, or nitrogen and hydrogen. In some embodiments, fluorine may also be present within the plasma. In some embodiments, the surfaces may be activated using a wet cleaning process, e.g., by exposing the surfaces to an aqueous ammonia solution. In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

Directly forming direct dielectric bonds between the first and second substrates may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH₂ groups), it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C. for a duration of about 5 minutes or more, such as about 15 minutes. Typically, the bonds will strengthen over time even without the application of heat. Thus, in some embodiments, the method does not include heating the substrates.

In embodiments where the substrates are bonded using hybrid bonds, the method may further include planarizing or recessing the metal features below the field surface before contacting and bonding the dielectric material layers. After the dielectric bonds are formed, the substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBI®, each of which are commercially available from Adeia, San Jose, CA, USA.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure.

1. An integrated cooling assembly comprising:
a semiconductor device; and
a heat pipe attached to a backside of the semiconductor device, wherein:
the heat pipe comprises an organic material;
the heat pipe comprises a shell defining a heat pipe chamber, the shell having an inner surface and an outer surface; and
the inner surface of the heat pipe chamber includes a wick material thereupon.

2. The integrated cooling assembly of claim 1, wherein the organic material comprises a polymer.

3. The integrated cooling assembly of claim 1, wherein the heat pipe comprises a composite material comprising the organic material and thermally conductive particulates.

4. The integrated cooling assembly of claim 1, wherein the heat pipe is attached to the backside of the semiconductor device with adhesive.

5. The integrated cooling assembly of claim 1, wherein:
a region of the outer surface of the heat pipe includes a dielectric layer deposited thereupon;
the dielectric layer is disposed between the region of the outer surface of the heat pipe and the backside of the semiconductor device; and
the heat pipe is attached to the backside of the semiconductor device using direct dielectric bonds formed between the dielectric layer and the backside of the semiconductor device.

6. The integrated cooling assembly of claim 5, wherein the backside of the semiconductor device further includes conductive features thereupon.

7. The integrated cooling assembly of claim 6, wherein:
the dielectric layer further includes conductive features thereupon; and
the heat pipe is attached to the backside of the semiconductor device using direct hybrid bonds comprising the direct dielectric bonds and direct bonds formed between the conductive features disposed in the backside of the semiconductor device and the conductive features disposed in the dielectric layer.

8. The integrated cooling assembly of claim 6, wherein the heat pipe is attached to the backside of the semiconductor device using direct bonds.

9. The integrated cooling assembly of claim 1, wherein the heat pipe is attached to the backside of the semiconductor device via a flexible material structure comprising an organic material.

10. The integrated cooling assembly of claim 9, wherein the flexible material structure comprises a composite material comprising the organic material and thermally conductive particulates.

11. The integrated cooling assembly of claim 9, wherein the flexible material structure comprises one or more metal vias.

12. The integrated cooling assembly of claim 9, wherein:
a region of the outer surface of the heat pipe includes a dielectric layer deposited thereupon;
the dielectric layer is disposed between the region of the outer surface of the heat pipe and the flexible material structure;
the heat pipe is attached to the flexible material structure using direct dielectric bonds formed between the dielectric layer and the flexible material structure; and
the flexible material structure is attached to the backside of the semiconductor device using direct dielectric bonds formed between the dielectric layer and the backside of the semiconductor device.

13. (canceled)

14. The integrated cooling assembly of claim 12, wherein:
the flexible material structure further includes conductive features thereupon;
the backside of the semiconductor device further includes conductive features thereupon;
the flexible material structure further includes conductive features thereupon; and
the flexible material structure is attached to the backside of the semiconductor device using direct hybrid bonds comprising the direct dielectric bonds and direct bonds formed between the conductive features disposed in the backside of the semiconductor device and the conductive features disposed in the flexible material structure.

15. The integrated cooling assembly of claim 12, wherein:
the flexible material structure further includes conductive features thereupon; and
the heat pipe is attached to the flexible material structure using direct bonding.

16. The integrated cooling assembly of claim 1, further comprising:
one or more dummy chiplets attached to the heat pipe, wherein the one or more dummy chiplets are attached to a casing via thermal interface material.

17. The integrated cooling assembly of claim 1, wherein the backside of the semiconductor device forms a portion of the shell of the heat pipe such that the backside of the semiconductor device forms a portion of the inner surface of the heat pipe chamber.

18. The integrated cooling assembly of claim 17, wherein the wick material extends across the portion of the backside of the semiconductor device that forms the portion of the shell.

19. The integrated cooling assembly of claim 18, wherein the wick material that extends across the portion of the backside of the semiconductor device is dendritic copper grown on the backside of the semiconductor device.

20. The integrated cooling assembly of claim 1, wherein:
the heat pipe comprises a first portion comprising the organic material and a second portion comprising a metal material; and
a region of the first portion of the heat pipe is attached to the backside of the semiconductor device.

21. The integrated cooling assembly of claim 1, wherein:
the heat pipe has a proximal end and a distal end;
the proximal end of the heat pipe is attached to the backside of the semiconductor device; and
the distal end of the heat pipe is attached to a heat sink.

22-39. (canceled)
